(19) United States
(12) Patent Application Publication
(10) Pub. No.: US 2008/0092820 A1
(43) Pub. Date: Apr. 24, 2008

(54) EVAPORATOR HAVING MULTI-LAYERED CONICAL SLIT NOZZLES FOR VACUUM THERMAL EVAPORATION

(75) Inventors: Seong-Moon KIM, Seoul (KR); Kwang-Ho JEONG, Gyeonggi-do (KR); Hyun SEO, Gyeonggi-do (KR); Su-Jeong MOON, Gyeonggi-do (KR)

Correspondence Address: GREENBLUM & BERNSTEIN, P.L.C., 1950 ROLAND CLARKE PLACE, RESTON, VA, 20191, US

(73) Assignee: YAS CO., LTD., Gyeonggi-do (KR)

(21) Appl. No.: 11/869,289

(22) Filed: Oct. 9, 2007

(30) Foreign Application Priority Data
Oct. 23, 2006 (KR) 10-2006-0102745

(51) Int. Cl. C23C 16/448

(52) U.S. Cl. 118/726

(57) ABSTRACT

The present invention relates to an evaporator for vacuum thermal evaporation, and more particularly, to an evaporator having multi-layered conical slit nozzles, which can form a large-area uniform thin film and improve the efficiency of use of a material to be deposited. The evaporator includes a cylindrical crucible 110 with an open top face, and a nozzle unit 120 having a cylindrical body portion 121 assembled to the top face of the crucible 110, wherein the body portion 121 is provided with multi-layered conical slits 122 formed at an upper periphery of the body portion 121 while being bored through the body portion, and an evaporation tube 123 connected to the slits 122 while penetrating through a lower face of the body portion 121. The multi-layered conical slit nozzles provide a spouting distribution of a material to be deposited, which can increase the thickness uniformity of a deposited thin film and improve the efficiency of use of the material to be deposited.

### BACKGROUND OF THE INVENTION

1. Field of the Invention

The present invention relates to an evaporator for vacuum thermal evaporation, and more particularly, to an evaporator having multi-layered conical slit nozzles, wherein a material to be evaporated in the evaporator can be deposited on a substrate with an improved efficiency of use of the material, thereby forming a large-area uniform thin film.

2. Description of the Related Art

Generally, various thin-film forming techniques are used to fabricate semiconductor devices or flat panel display devices. One of them is a vacuum thermal evaporation method. The vacuum thermal evaporation method is a method of forming a thin film by placing a substrate at an upper side within a vacuum container, and heating an evaporator, which is placed below the substrate and contains a material to be evaporated, so that the evaporated material can be deposited on the substrate.

A point evaporator is most popularly used in the vacuum thermal evaporation method. The point evaporator includes a cylindrical container with a spouting portion. A material to be evaporated is filled into the cylindrical container that in turn is heated to evaporate the material, so that the evaporated material spouts from the container toward a substrate to form a thin film. However, since the point evaporator causes most of the evaporated material to spout therefrom in a direction directed by the spouting portion, it has a problem in that a large-area uniform thin film cannot be obtained.

In order to solve this problem, the present inventor proposed an evaporator having a conical nozzle, which enables a uniform thin film to be obtained even on a large-area substrate, in Korean Patent No. 434438 issued on May 24, 2004.

FIGS. 1 and 2 show major portions of the evaporator in the Korean patent. The evaporator 1 includes a cylindrical crucible 10 with an open top face and a cylindrical insert unit 20 assembled to the top face of the crucible 10.

The insert unit 20 is provided with a nozzle tube 21 with a conical shape as a whole, and an evaporation tube 22 connected to the nozzle tube 21 while penetrating through a lower portion of the insert unit.

In the evaporator having a conical nozzle, a deposition material spouts through the evaporation tube 22 and the conical nozzle tube 21 to form a thin film with a uniform thickness even on a large-area substrate.

However, although the conventional evaporator having a conical nozzle can provide a large-area uniform thin film, most of the deposition material spouting through the conical nozzle is directed to outer peripheral areas of the substrate, resulting in a decrease in the efficiency of use of material.

### SUMMARY OF THE INVENTION

Accordingly, the present invention is conceived to solve the aforementioned problems. An object of the present invention is to provide an evaporator that can form a thin film with a uniform thickness on a large-area substrate without rotation of the substrate and have a high efficiency of use of a material to be evaporator.

An evaporator having multi-layered conical slit nozzles for vacuum thermal evaporation according to the present invention comprises a cylindrical crucible with an open top face; and a nozzle unit having a cylindrical body portion assembled to the top face of the crucible, wherein the body portion is provided with multi-layered conical slits formed at an upper periphery of the body portion while being bored through the body portion, and an evaporation tube connected to the slits while penetrating through a lower face of the body portion.

### BRIEF DESCRIPTION OF THE DRAWINGS

The above and other objects, features and advantages of the present invention will become apparent from the following description of a preferred embodiment given in conjunction with the accompanying drawings, in which:

FIG. 1 is a perspective view showing a conventional evaporator having a conical nozzle;

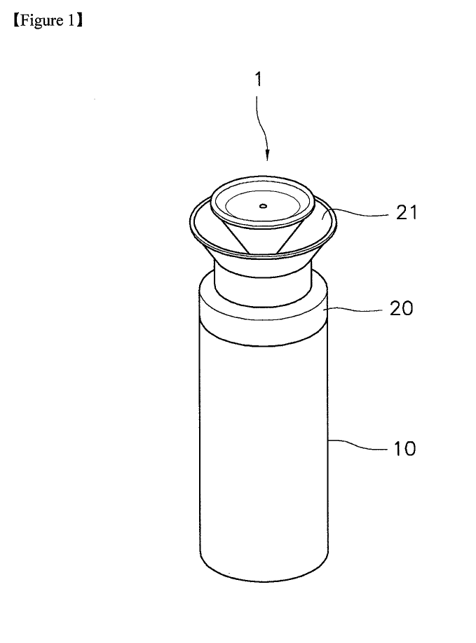

FIG. 2 is a sectional view showing an insert unit of the conventional evaporator of FIG. 1;

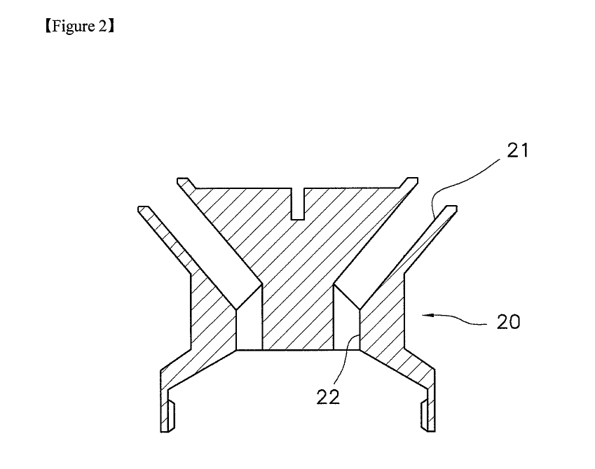

FIG. 3 is a perspective view showing an evaporator having multi-layered conical slit nozzles according to an embodiment of the present invention;

FIG. 4 is a sectional perspective view showing an insert unit of the evaporator of the present invention;

FIG. 5 is a schematic view showing a vacuum thermal evaporation method using the evaporator of the present invention; and

FIG. 6 is a graph showing comparison results of spouting distributions in the conventional evaporator having a conical nozzle and the evaporator having multi-layered conical slit nozzles according to the present invention.

### DETAILED DESCRIPTION OF THE INVENTION

Hereinafter, a preferred embodiment of the present invention will be described in detail with reference to the accompanying drawings.

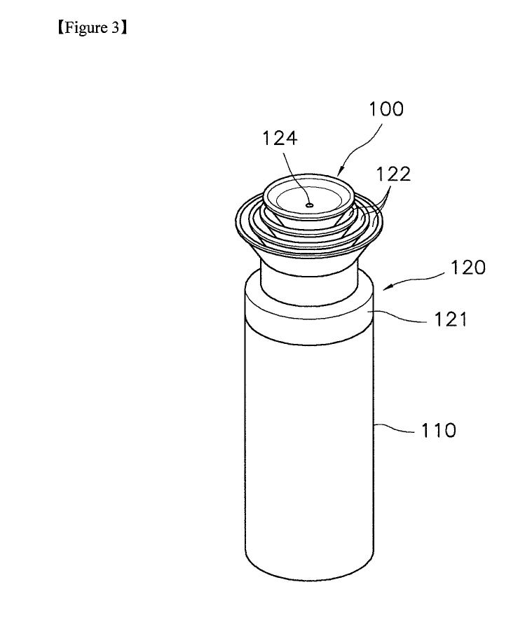

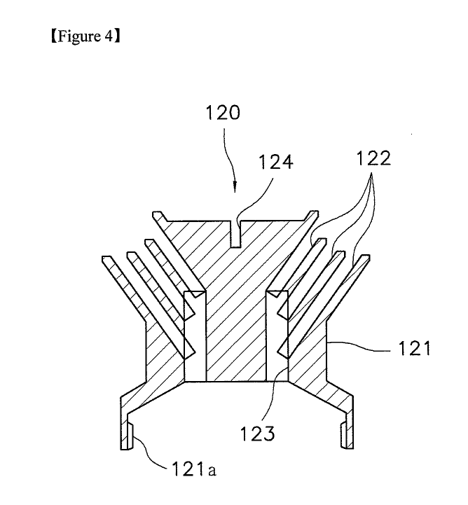

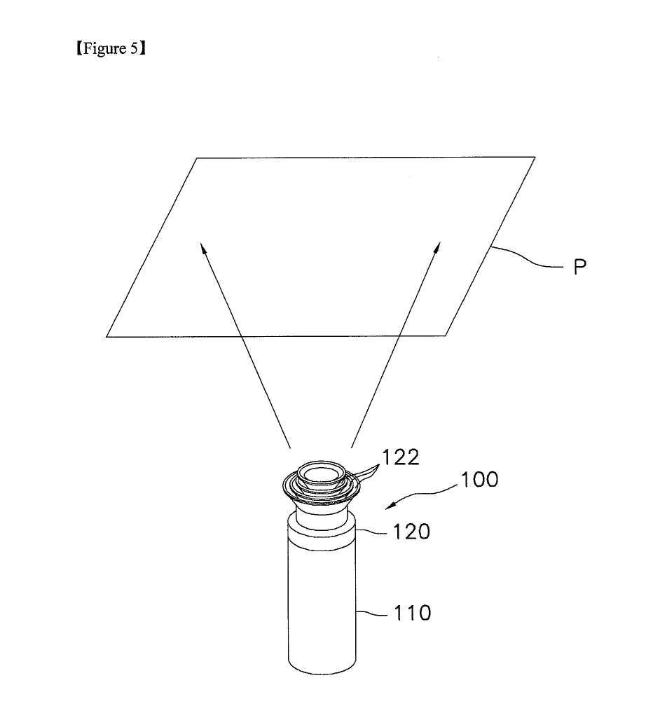

FIGS. 3 to 5 show an evaporator having multi-layered conical slit nozzles according to an embodiment of the present invention. Specifically, FIG. 3 shows a perspective view of the evaporator, FIG. 4 shows a sectional view of an insert unit of the evaporator, and FIG. 5 shows a schematic view of a vacuum thermal evaporation method using the evaporator of the present invention.

As shown in FIGS. 3 and 4, the evaporator having multi-layered conical slit nozzles according to the present invention includes a cylindrical crucible 110 with an open top face, and a nozzle unit 120 having a cylindrical body portion 121 assembled to the top face of the crucible 110, wherein the body portion 121 is provided with multi-layered conical slits 122 formed at an upper periphery of the body portion 121 while being bored through the body portion, and an evaporation tube 123 connected to the slits 122 while penetrating through a lower face of the body portion 121.

A lower end of the body portion 121 is provided with a coupling means 121a for assembling the body portion to the crucible 110.

The evaporator having multi-layered conical slit nozzles according to the present invention is different from the conventional evaporator having a single conical nozzle, in that a plurality of conical nozzles are formed in a multi-layered fashion in the insert or nozzle unit. This difference in their structures produces an advantageous effect of improvement in the efficiency of use of a material to be deposited.

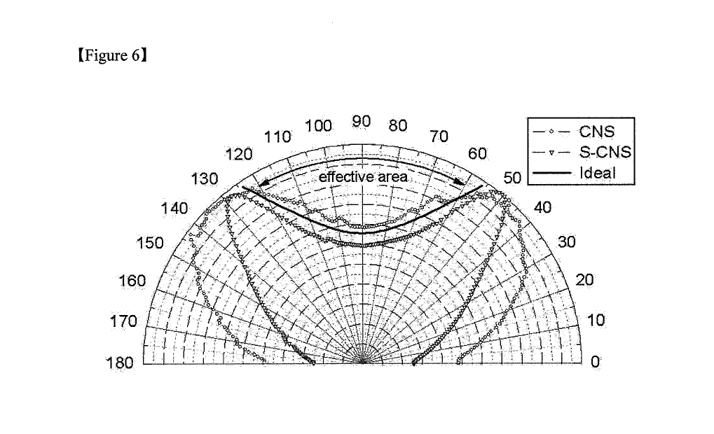

Comparison results of spouting distributions in the conventional evaporator having a single conical nozzle and the evaporator having multi-layered conical slit nozzles according to the present invention will be described in greater detail with reference to FIG. 6.

When spouting distributions are measured while applying simple cylindrical nozzles to an evaporator that is to be used under a vacuum condition, a spouting distribution in a case where a material spouts through a plurality of small-diameter cylinders has greater directionality than that in a case where the material spouts through a single large-diameter cylinder (i.e., has higher and steeper centers at peak regions in the spouting distribution graph). When this tendency is applied to evaporators having one or more conical nozzles, a spouting distribution of an evaporator having multi-layered conical nozzles has greater directionality than that of an evaporator having a single conical nozzle. Therefore, it is possible to minimize the amount of a material to be wasted outside a substrate. When a spouting distribution of a conventional evaporator having a conical nozzle (CNS) is compared with a spouting distribution of an evaporator having multi-layered conical nozzles according to the present invention (S-CNS) in the graph of FIG. 6, it can be found that although both the cases have similar distributions in effective areas, the evaporator of the present invention represents less spouting of the material than the conventional evaporator in other areas outside the effective areas. Thus, the evaporator having multi-layered conical nozzles according to the present invention has an advantageous effect of improvement in the efficiency of use of a material to be deposited.

Next, a method of forming a thin film on a substrate using the evaporator having multi-layered conical nozzles according to the present invention will be described below.

As shown in FIGS. 3 and 4, the crucible and the nozzle unit are coupled to each other using the coupling means 121a of the nozzle unit and a coupling means (not shown) of the crucible. Then, the evaporator composed of the nozzle unit and the crucible is heated up externally so that a material to be evaporated within the crucible is evaporated and spouts while sequentially passing through the evaporation tube and the conical nozzles of the nozzle unit, and is finally deposited on a substrate P placed above the evaporator, as shown in FIG. 5.

At this time, it is desirable to dispose multi-layered reflection plates on an upper surface of the nozzle unit so as to prevent a large amount of heat from escaping through the upper surface of the nozzle unit. The reflection plates are fixed using a fixing hole 124.

According to the present invention described above, a thin film with a uniform thickness is formed on a large-area substrate and the efficiency of use of a material to be deposited is improved by using multi-layered conical nozzles.

The aforementioned embodiment is an example for specifically illustrating the technical spirit of the present invention and the scope of the present invention is not limited to the embodiment or drawings.

What is claimed is:

1. An evaporator having multi-layered conical slit nozzles for vacuum thermal evaporation, comprising:
a cylindrical crucible with an open top face; and
a nozzle unit having a cylindrical body portion assembled to the top face of the crucible,
wherein the body portion is provided with multi-layered conical slits formed at an upper periphery of the body portion while being bored through the body portion, and an evaporation tube connected to the slits while penetrating through a lower face of the body portion.
